(19) United States
(12) Patent Application Publication
(10) Pub. No.: US 2006/0175290 A1
(43) Pub. Date: Aug. 10, 2006

(54) Photo resist stripping and de-charge method for metal post etching to prevent metal corrosion

(75) Inventors: Yuan-Bang Lee, Tongxiao Town (TW); Tzu-Yang Wu, Hsinchu (TW); Sheng-Liang Pan, Hsin-Chu (TW); Chung-Yuan Cheng, Hsin Chu City (TW); Sheng-Chieh Liu, Taichung City (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Company, Ltd.

(21) Appl. No.: 11/054,015

(22) Filed: Feb. 9, 2005

(51) Int. Cl. C23F 1/00; H01L 21/302; B44C 1/22; C03C 15/00

(52) U.S. Cl. 216/67; 438/710

(57) ABSTRACT

An pure H₂O stripping process for etched metal wafers effectively solves the metal corrosion deficiencies induced by O₂, N₂ plasma charging. The pure H₂O plasma stripping releases and neutralizes the storage of positive charge accumulated in the wafer, reduces chlorine concentration, and effectively strips the photoresist and etching residue. Thereby reducing metal corrosion and increases the anti-metal corrosion window. The pure H₂O plasma stripping requires no additional equipment and or steps.

### BACKGROUND

The present invention generally relates to a photoresist stripping and de-charge method for metal post etching to prevent metal corrosion and, in particular, to a pure H₂O stripping process for etched metal wafers that effectively solves metal corrosion deficiencies induced by O₂, N₂ plasma charging.

Present semiconductors commonly use multi-level metallization architecture containing several metal layers. In these modern metal structures, the use of dissimilar materials in multi-levels such as Ti/TiN/Al—Si—Cu/TiN, Ti/Al—Si—Cu/TiN, Ti/TiN/Al—Cu/TiN or TiN/Al—Cu/TiN, increases the chance of electrochemical corrosion.

A metal will corrode when the EMF (electromotive force) between different conductive materials is positive with respect to the equilibrium for the corrosion reaction (i.e., galvanic corrosion). If a structure is floating, the charges collected are to be accumulated within the floating structure, thereby elevating the potential between different conductor materials. In addition, the positive charges collected in the capacitor of the P+ active and the n-well structure on the PMOS would enhance the metal corrosion during stripping process. Exemplary governing equations describing charging induced metal corrosion are:
Al→Al³⁺+3e⁻
3H⁺+3e⁻→1.5H₂

There are several conditions that may increase corrosion probability. First, charging is mainly induced by an O₂/N₂ plasma stripping process. Second, cumulative positive charging accelerates the reaction and results in severe metal corrosion when a moisture-rich environment exists. Third, metallization with a high antenna ratio enhances the electrochemical reaction. Further, the electrochemical corrosion can be accelerated by the presence of Cl⁻. A Chlorine induced metal corrosion may be described by the following exemplary equations:
Cl₂+H₂O→HOCl+HCl
2Al+6HCl→Al₂Cl₆+3H₂
Al₂Cl₆+4H₂O→2AlO(OH)+6HCl

Current metal etching processes include factors that can lead to an increased probability of post-etching corrosion and associated deleterious effects on a semiconductor chip. Traditional metal etching includes a main etching chamber and dry stripping chamber, however some devices enable etching and stripping in the same chamber. A prior art metal etching and stripping process is shown in FIG. 1.

First, a wafer having one or more metal layers in a multi-level metallization architecture and a patterned photoresist layer is provided in an etching chamber as shown by 101. The wafer is dry etched as shown by 102. Dry etching is commonly used in the production of semiconductor wafers due to its ability to better control the etching process and reduce contamination levels. Dry processing effectively etches the desired layers through the use of gases, e.g., a chemically reactive gas, or through physical bombardment of heavy atoms. In one prior art process, a radio frequency energy source is used to activate fluorine-based or chlorine-based gases which act as etchants. The RF energy ionizes the gas and forms an etching plasma, which reacts with the wafer to form volatile products which are then pumped away. As a result of the metal etching, there is generally a positive charge residue on the wafer as shown by 103. After the metal etching, the wafer is transferred to stripping chamber, where the residue photo resist and metallic polymer are burnt and removed in a stripping process as shown by 104 and 105.

A prior art etching chamber of a Centura Metal Etch DPS system is accompanied by a microwave type advance strip and passivation (ASP) dry stripper. In the process, an in-situ H₂O plasma treatment prior to the dry strip process is undertaken to remove chlorine-related compounds. The stripper then uses a downstream O₂/N₂/H₂O plasma for the dry stripping process shown in 105. In the dry stripping or “plasma ashing,” the wafer is placed into a chamber under a vacuum and oxygen or another known gas is introduced and subjected to RF power thereby creating oxygen radicals. The radicals react with the photoresist to oxidize it into water, carbon monoxide, and carbon dioxide. After being exposed to the O₂/N₂/H₂O plasma, a charge residue remains and likely is increased as a result of the exposure, as shown by 105. The wafer is then transferred to a load lock and removed from the stripping chamber as shown by 106. The wafer then is ready for further processing such as additional etching or stripping. While waiting for the next process, such as wet stripping, the metal layers may corrode when the potential difference across the interface in the electrolytic environment is positive with respect to the equilibrium potential for the corrosion reaction. In this prior art metal etching process, there is no treatment for charge removal.

In some prior art metal etching processes, an additional step of H₂O baking without microwaves is performed to drive off some residual charge after stripping. As shown in FIG. 2, a wafer is provided 201, etched in the main chamber 202, and transferred to a stripping chamber 203. Stripping commences with bombardment of microwaves 204 and the wafer is then exposed to a plasma of O₂, N₂ and H₂O as shown by 205. Without an RF source, the wafer undergoes an H₂O bake to reduce residual charge as shown by 208. The wafer is then transferred from the stripping chamber to await further processing as shown by 206. This process, however, in addition to adding another step and significant cost, does not substantially eliminate the charge on the wafer.

As noted above, corrosion of the metal layers can be enhanced by plasma stripping which generates charge accumulation on the wafer. The disclosure presents subject matter to obviate deficiencies in the prior art and solve the metal corrosion problem induced by plasma charging. The disclosed subject matter describe a pure H₂O plasma stripping in a stripping chamber to release and neutralize the storage of positive charges and reduce chlorine concentration. In addition, disclosed embodiments of the subject matter may require no additional equipment.

These and other advantages of the disclosed subject matter will be readily apparent to one skilled in the art to which the disclosure pertains from a perusal of the claims, the appended drawings, and the following detailed description of the preferred embodiments.

### BRIEF DESCRIPTION OF THE DRAWINGS

FIG. 1 is a metal etching process.

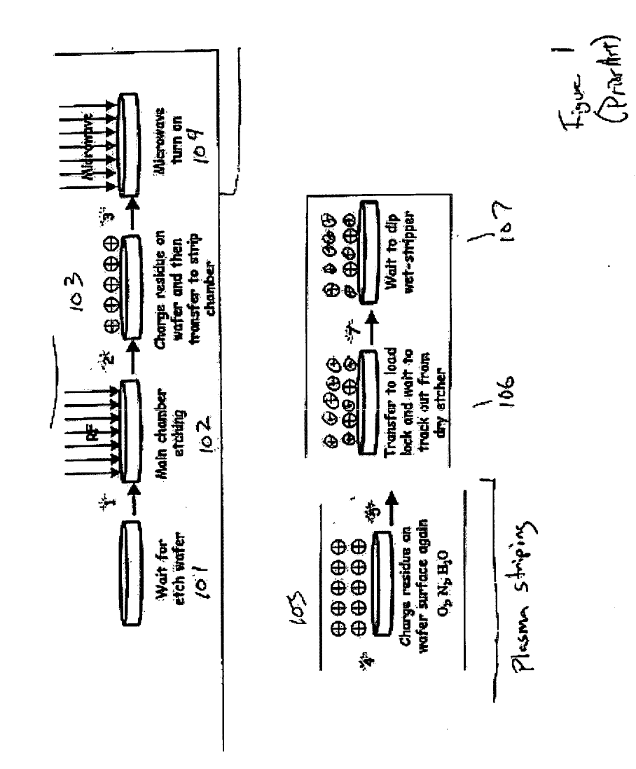

FIG. 2 is a prior art metal etching process with a baking step to reduce residual charge.

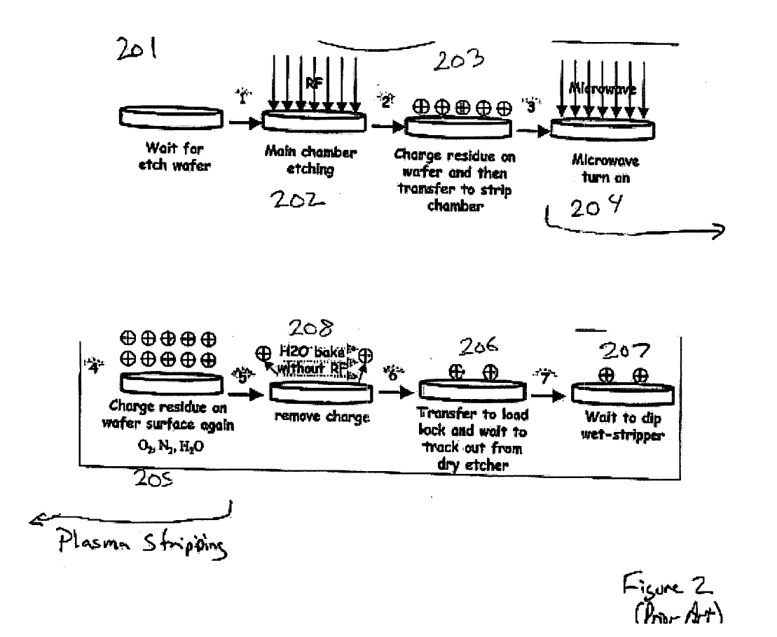

FIG. 3 is a metal etching process using a pure H₂O plasma to substantially eliminate a residue charge on a wafer.

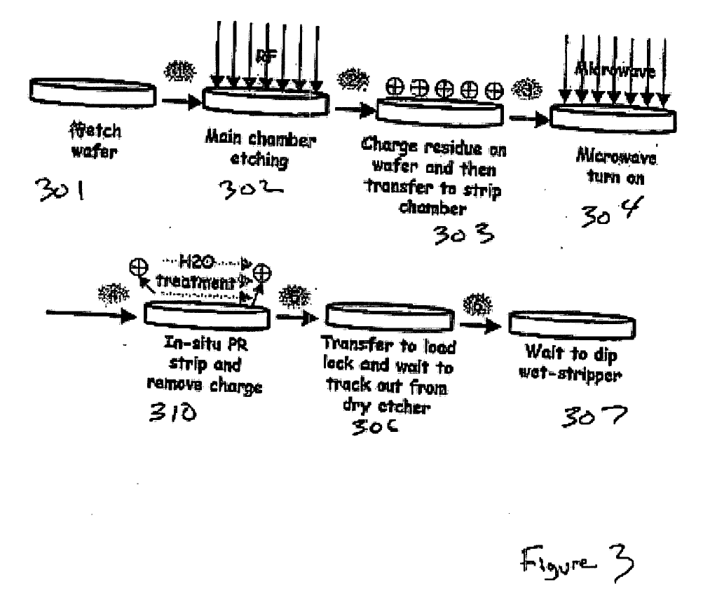

### DETAILED DESCRIPTION

An embodiment of a metal etching process includes a main etching chamber and dry stripping chamber. First, a wafer having one or more metal layers in a multi-level metallization architecture and a patterned photo resist layer is provided to an etching chamber as shown by 301. The wafer is dry etched as shown by 302. As a result of the metal etching, there is generally a positive charge residue on the wafer as shown by 303. After the metal etching, the wafer is transferred to stripping chamber, where the residue photoresist and metallic polymer are burnt and removed in a stripping process as shown by 304 and 310. A substantially pure H₂O plasma is used to strip the photoresist and etch residue. The H₂O plasma stripping neutralizes the storage of positive charges and reduces chlorine concentration. The wafer is then transferred to a load lock and removed from the stripping chamber as shown by 306. The wafer may then be subjected to further processing such as additional etching or stripping. After the pure H₂O plasma treatment, any potential difference between the metal layers has been substantially eliminated and thus the probability of corrosion is also reduced.

In order to obtain the desired results, the pure H₂O plasma treatment may be the last treatment in the stripping process. While some prior art processes use an H₂O plasma treatment in the stripping process, the H₂O plasma treatment is followed by an N₂, O₂ stripping step resulting in recharging of the wafer.

In accordance with an embodiment of the present disclosure, the pure H₂O plasma treatment without O₂/N₂ in the stripping chamber of the metal etching process acts to release and neutralize positive charging storage, reduces chlorine concentration, and can be practiced without additional equipment or cost. The disclosed subject matter thus enhances the anti-metal corrosion process window.

Experimental results of metal corrosion comparing the prior art stripping processes of N₂/O₂/H₂O plasma with and without an H₂O bake and the pure H₂O plasma stripping on the control wafer with high antenna ratio of 1000 is shown in Table 1.

TABLE 1

| Method | 20 Min | 40 Min | 60 Min | 2 Hours | 3 Hours | 4 Hours |
|---|---|---|---|---|---|---|
| Standard | Free | Slightly | Serious | Serious | Serious | Serious |
| H₂O Bake | Free | Free | Slightly | Serious | Serious | Serious |
| Pure H₂O | Free | Free | Free | Free | Free | Free |
| plasma Ashing | | | | | | |

As shown in Table 1, the pure H₂O plasma ashing treatment extended the metal corrosion window from 20 minutes, achieved by the standard prior art method, to over 4 hours. The pure H₂O plasma ashing treatment also showed significant advantages over the H₂O bake with an added advantage of not introducing a new step or further associated costs. The advantage of a larger anti-corrosion window adds flexibility in the manufacturing process and reduces wafer defects related to corrosion. In addition to reducing charge induced corrosion in the metal layers, the pure H₂O plasma also reduces the residual chlorine concentration on the wafers.

Table 2 shows experimental comparisons of residual chlorine concentration of the wafers from the prior art methods and the pure H₂O plasma treatment.

TABLE 2

| Method | CL⁻ (ng/cm²) |
|---|---|
| O2/N2/H2O (standard stripping) | 1.6 |
| Extra H2O Baking | 0.4 |
| Pure H2O Plasma | 0.3 |

The in-situ pure H₂O plasma process reduces chlorine concentration by five fold in comparison to the O₂/N₂/H₂O stripping process. The pure H₂O plasma process is also favorable to the prior art H₂O baking method. From Tables 1 and 2 it is clear that from a post-etching corrosion perspective, the pure H₂O plasma stripping process is favorable to the prior art methods. In addition, with respect to stripping rate, the pure H₂O plasma stripping process shows only a slight reduction in stripping rates as compared to the prior art.

Table 3 shows the respective stripping rates for the prior art processes and the pure H₂O plasma.

TABLE 3

| Method | PR strip rate (A/min) |
|---|---|
| O2/N2/H2O (standard stripping) | 35000 |
| Pure H2O Plasma | 20000 |

Pure H₂O plasma stripping effectively solves the metal corrosion deficiencies induced by plasma charging in prior art processes. The pure H₂O plasma stripping releases and neutralizes the storage of positive charge accumulated in the wafer, reduces chlorine concentration, and possesses an effective stripping rate. In addition to these advantages, the pure H₂O plasma stripping requires no additional equipment and or steps which makes it more cost effective.

While preferred embodiments of the present inventive system and method have been described, it is to be understood that the embodiments described are illustrative only and that the scope of the embodiments of the present inventive system and method is to be defined solely by the appended claims when accorded a full range of equivalence, many variations and modifications naturally occurring to those of skill in the art from a perusal hereof.

What we claim is:

1. In a method for removing a multi-level metallization architectured semiconductor wafer by a plasma having a constituent which leaves a residual electrical charge on a metal surface of the semiconductor wafer and therefore promotes subsequent corrosion, the improvement wherein the plasma consists essentially of H₂O so that the residual charge on the metal surface of the semiconductor is substantially eliminated.

2. The method of claim 1, wherein the multi-level metallization architectured semiconductor wafer includes metals layers selected from the group comprising Ti, TiN, and Al—Si—Cu/Al—Cu.

3. The method of claim 2, wherein the metals layers are Ti/TiN/Al—Si—Cu/TiN respectively or Ti/TiN/Al—Cu/TiN respectively.

4. The method of claim 2, wherein the metal layers are Ti/Al—Si—Cu/TiN respectively or TiN/Al—Cu/TiN respectively.

5. A method for reducing chlorine concentration during photo resist stripping and discharge, comprising:
providing a semiconductor wafer with one or more metal layers and a photo-resist layer;
selectively etching the semiconductor wafer; and
selectively stripping the photo resist layer by exposure to a plasma;
wherein the plasma finishing the stripping step is a substantially pure H₂O plasma.

6. The method of claim 5, wherein the one or more metal layers are selected from the group comprising of Ti, TiN, and Al—Si—Cu/Al—Cu.

7. The method of claim 6, wherein the one or more metal layers are Ti/TiN/Al—Si—Cu/TiN respectively or Ti/TiN/Al—Cu/TiN respectively.

8. The method of claim 6, wherein the one or more metal layers are Ti/Al—Si—Cu/TiN respectively or TiN/Al—Cu/TiN respectively.

9. The method of claim 5, wherein the steps of etching and stripping are performed in the same chamber.

10. The method of claim 5, wherein the steps of etching and stripping are performed in different chambers.

11. A method for reducing a residual charge on a metal layer of a semiconductor accumulated during photo resist stripping and discharge, comprising:
providing a semiconductor wafer with one or more metal layers and a photo-resist layer;
selectively etching the semiconductor wafer;
selectively stripping the photo resist layer by exposing to a plasma;
wherein the plasma consists essentially of an H₂O plasma for substantially the turn-on RF or microwave stripping step.

12. The method of claim 11, wherein the one or more metal layers include metals layers selected from the group comprising Ti, TiN, and Al—Si—Cu/Al—Cu.

13. The method of claim 11, wherein the metals layers are Ti/TiN/Al—Si—Cu/TiN respectively or Ti/TiN/Al—Cu/TiN respectively.

14. The method of claim 11, wherein the metal layers are Ti/Al—Si—Cu/TiN respectively or TiN/Al—Cu/TiN respectively.

15. The method of claim 11, wherein the steps of etching and stripping are performed in the same chamber.

16. The method of claim 11, wherein the steps of etching and stripping are performed in different chambers.

17. A method for increasing the post stripping anti-metal corrosion process window in the manufacture of a semiconductor wafer, comprising:
providing a semiconductor wafer with one or more metal layers and a photo-resist layer;
selectively etching the semiconductor wafer; and
selectively stripping the photo resist layer by exposure to a plasma;
wherein the plasma consists essentially of an H₂O plasma for substantially the turn-on RF or microwave stripping step.

18. The method of claim 17, wherein the one or more metal layers include metals layers selected from the group comprising Ti, TiN, and Al—Si—Cu/Al—Cu.

19. The method of claim 18, wherein the metals layers are Ti/TiN/Al—Si—Cu/TiN respectively or Ti/TiN/Al—Cu/TiN respectively.

20. The method of claim 18, wherein the metal layers are Ti/Al—Si—Cu/TiN respectively or TiN/Al—Cu/TiN respectively.
